(19) United States
(12) Patent Application Publication
(10) Pub. No.: US 2026/0090065 A1
(43) Pub. Date: Mar. 26, 2026

(54) TRANSISTOR HAVING A GATE REGION WITH A UNIFORM GATE LENGTH AND A BODY CONTACT REGION ABUTTED TO A CONDUCTION CHANNEL UNDER THE GATE REGION TO IMPROVE MITIGATION OF THE KINK EFFECT

(71) Applicant: QUALCOMM Incorporated, San Diego, CA (US)

(72) Inventors: Ravi Pramod Kumar Vedula, San Diego, CA (US); Hyunchul Jung, San Diego, CA (US); Abhijeet Paul, San Diego, CA (US)

(21) Appl. No.: 18/896,023

(22) Filed: Sep. 25, 2024

(51) Int. Cl. H01L 29/49; H01L 21/265; H01L 21/3215; H01L 21/84; H01L 27/12; H01L 29/66; H01L 29/78

(52) U.S. Cl. CPC H10D 64/671; H10D 30/022; H10D 30/601; H10D 30/637; H10D 86/01; H10D 86/201; H10P 30/204; H10P 30/21; H10P 32/302

(57) ABSTRACT

Aspects include a transistor having a gate region with a uniform gate length and a body contact region abutted to a conduction channel under the gate region to improve mitigation of the kink effect, and related methods. The transistor includes the conduction channel formed from a semiconductor layer. A source region and a drain region of the transistor are formed on opposite sides of the conduction channel in the semiconductor layer. A gate region is formed adjacent to the conduction channel. The gate region has a gate length and a gate width. The transistor has a body contact region having a second polarity and directly adjacent to the second side of the conduction channel creating a body interface between the body contact region and the conduction channel. The gate length is uniform throughout the entire gate width including where the body contact region is directly adjacent to the conduction channel.

### TECHNICAL FIELD

The field of the disclosure relates to field-effect transistors (FETs), and more particularly to FET designs formed as silicon-on-insulator (SOI) substrates.

### BACKGROUND

Transistors are essential components in modern electronic devices, and large numbers of transistors are employed in integrated circuits (ICs) therein. For example, components such as central processing units (CPUs) and memory systems each employ a large quantity of transistors for logic circuits and memory devices. Transistors are also employed in radio-frequency (RF) devices, such as modern smart phones, and other portable devices have extended the use of different wireless links with a variety of technologies in different radio frequency bands.

Field-effect transistors (FETs) can be formed as silicon-on-insulator (SOI) substrate FETs. SOI substrate FETs are formed in thin layers of silicon that are isolated from the main body of the SOI wafer handle substrate by a layer of an electrical insulator, usually silicon dioxide. The silicon layer thickness ranges from several microns (i.e., micrometers (μm)) for electrical power switching devices to less than five hundred (500) Angstroms (Å) for high-performance microprocessors. FETs include a gate, drain, source, and body terminals. The body terminal controls the electrical characteristics of the FET by affecting the threshold voltage and channel conductivity. Many discrete FETs internally couple the body terminal with the source terminal. In an N+ metal oxide silicon (NMOS) FET, the body terminal and source terminal are typically connected to ground. In an PMOS FET, the body terminal and source terminal are typically connected to the highest voltage in a circuit in which the PMOS FET is deployed.

During operation of a FET, electron hole pairs are generated in the conduction channel. In particular, an inversion region is created under the gate terminal which conducts electrons between the drain and source terminals and the paired holes form a depletion region adjacent to the inversion region. The kink effect occurs due to the accumulation of holes in the depletion region of the operating FET. This accumulation of holes in the FET increases the internal resistance of the FET which reduces the threshold voltage leading to runaway drain current at high drain voltages (V_{ds}), which appears as a “kink” in the output characteristics of the FET.

### SUMMARY OF THE DISCLOSURE

Aspects disclosed herein include a transistor having a gate region with a uniform gate length and a body contact region abutted to a conduction channel under the gate region to improve mitigation of the kink effect, and related methods. The transistor is provided that includes the conduction channel formed from a semiconductor layer (i.e., silicon). The transistor may be a silicon-on-insulator (SOI) transistor as an example. A source region and a drain region of the transistor are formed on opposite sides of the conduction channel in the semiconductor layer by implanting or diffusing doping material of a first polarity in the semiconductor layer. A gate region is formed on an insulating layer that is adjacent to the conduction channel to generate an electric field in the conduction channel and control the flow of current in the conduction channel. The gate region has a gate length and a gate width. The transistor has a body contact region having a second polarity and directly adjacent to the second side of the conduction channel creating a body interface between the body contact region and the conduction channel. The gate length is uniform throughout the entire gate width including where the body contact region is directly adjacent to the conduction channel.

In this regard, when bias between the gate and source regions (Vgs) is applied and increased, an electric field under the gate region is formed that repels holes (the majority carriers in a p-well (a.k.a. p-type doped substrate for an n-type transistor)) away from the region directly under the gate forming a depletion region. The body contact region pulls holes formed in the depletion region through the body interface with the conduction channel. Since the gate length is uniform throughout the gate width, the holes are pulled without negatively impacting the performance of the transistor. In short, having a uniform gate length can reduce threshold voltage variations, inconsistent channel lengths, timing issues, enhanced short-channel effects, and increased variability, all of which can degrade the overall performance and reliability of the complementary metal-oxide-semiconductor (CMOS) transistor. Additionally, by abutting the body contact region to the conduction channel while maintaining the gate length, more body interfaces may be added to design transistors to pull more holes created at higher Vgs voltages and flatten out the kink effect at those higher Vgs voltages.

In an aspect, a transistor is provided. The transistor comprises an insulation layer extending in a first direction and a second direction orthogonal to the first direction and a semiconductor layer extending in the first direction and the second direction, the semiconductor layer adjacent to the insulation layer in a third direction orthogonal to the first direction and the second direction. The semiconductor layer comprises a conduction channel, a source region of a first polarity and adjacent to a first side of the conduction channel, a drain region of the first polarity and adjacent to a second side of the conduction channel opposite the first side in the first direction, a gate region extending in the first direction and the second direction, the gate region adjacent to the conduction channel in the third direction, the gate region having a gate length extending in the first direction and a gate width extending in the second direction, wherein the gate length is uniform throughout the gate width, and a body contact region having a second polarity and directly adjacent, in the first direction, to the first side of the conduction channel.

In another aspect, a method of fabricating a transistor to improve mitigation of a kink effect. The method comprises fabricating an insulation layer extending in a first direction and a second direction orthogonal to the first direction and fabricating a semiconductor layer extending in the first direction and the second direction, the semiconductor layer adjacent to the insulation layer in a third direction orthogonal to the first direction and the second direction. Fabricating the semiconductor layer comprises fabricating a conduction channel, fabricating a gate region extending in the first direction and the second direction, the gate region adjacent to the conduction channel in the third direction, the gate region having a gate length extending in the first direction and a gate width extending in the second direction, wherein the gate length is uniform throughout the gate width, fabricating a source region of a first polarity and adjacent to a first side of the conduction channel, fabricating a drain region of the first polarity and adjacent to a second side of the conduction channel opposite the first side in the first direction, and fabricating a body contact region having a second polarity and directly adjacent, in the first direction, to the first side of the conduction channel.

In another aspect, a NFET transistor is provided. The NFET transistor comprises an insulation layer extending in a first direction and a second direction orthogonal to the first direction and a semiconductor layer extending in the first direction and the second direction, the semiconductor layer adjacent to the insulation layer in a third direction orthogonal to the first direction and the second direction. The semiconductor layer comprises a conduction channel, a n-type source region adjacent to a first side of the conduction channel, a n-type drain region adjacent to a second side of the conduction channel opposite the first side in the first direction, a gate region extending in the first direction and the second direction, the gate region adjacent to the conduction channel in the third direction, the gate region having a gate length extending in the first direction and a gate width extending in the second direction, wherein the gate length is uniform throughout the gate width, and a p-type body contact region directly adjacent, in the first direction, to the first side of the conduction channel and the n-type source region.

### BRIEF DESCRIPTION OF THE FIGURES

FIG. 1A is a top view of a body butted to source (BBS) n-type transistor having a gate region with a non-uniform gate length;

FIG. 1B is a side view of the field-effect transistor (FET) at cut line A-A′ in FIG. 1A;

FIG. 1C is a side view of the FET at cut line B-B′ in FIG. 1A illustrating the difference in gate length between cut line B-B′ and cut line A-A′;

FIG. 1D is a side view of the FET at cut line C-C′ in FIG. 1A illustrating body interfaces between a conduction channel and body contact region;

FIG. 2A is a top view of an exemplary embodiment of an n-type transistor having a gate region with a uniform gate length and a body contact region abutted to a conduction channel under the gate region to improve mitigation of the kink effect;

FIG. 2B is a side view of the FET at cut line C-C′ in FIG. 2A;

FIG. 2C is a side view of the FET at cut line D-D′ in FIG. 2A;

FIG. 3A is a top view of an exemplary embodiment of a p-type transistor having a gate region with a uniform gate length and a body contact region abutted to a conduction channel under the gate region to improve mitigation of the kink effect;

FIG. 3B is a side view of the FET at cut line F-F′ in FIG. 3A;

FIG. 3C is a side view of the FET at cut line G-G′ in FIG. 3A;

FIG. 4A is a top view of another exemplary embodiment of an n-type transistor having a gate region with a uniform gate length and a body contact region abutted to a conduction channel under the gate region to improve mitigation of the kink effect;

FIG. 4B is a top view of another exemplary embodiment of a p-type transistor having a gate region with a uniform gate length and a body contact region abutted to a conduction channel under the gate region to improve mitigation of the kink effect;

FIG. 5A is a top view of another exemplary embodiment of an n-type transistor having a gate region with a uniform gate length and a body contact region abutted to a conduction channel under the gate region to improve mitigation of the kink effect;

FIG. 5B is a top view of another exemplary embodiment of a p-type transistor having a gate region with a uniform gate length and a body contact region abutted to a conduction channel under the gate region to improve mitigation of the kink effect;

FIG. 6 is a graph which illustrates a series of simulated current/voltage characteristic curves comparing the n-type transistor of FIGS. 1A-1C and the n-type transistor of FIG. 5A having a gate region with a uniform gate length and a body contact region abutted to a conduction channel under the gate region to improve mitigation of the kink effect over various operating temperatures and various gate voltages (Vg);

FIG. 7 is a flowchart illustrating an exemplary fabrication process for fabricating an FET having a gate region with a uniform gate length and a body contact region abutted to a conduction channel under the gate region to improve mitigation of the kink effect including, but not limited to, the transistors in FIGS. 2A-2C, 4A-4B, and 5A-5B;

FIGS. 8A-8C are a flowchart illustrating another exemplary fabrication process for fabricating an n-type transistor having a gate region with a uniform gate length and a body contact region abutted to a conduction channel under the gate region to improve mitigation of the kink effect, including, but not limited to, the n-type transistors in FIGS. 2A-2C, 4A, and 5A, and is applicable to the p-type transistors of FIGS. 3A-3C, 4B, and 5B;

FIGS. 9A-9H are exemplary fabrication stages during fabrication of the n-type transistor according to the fabrication process in FIGS. 8A-8C;

FIG. 10 is a block diagram of an exemplary wireless communications device that includes radio-frequency (RF) components comprising transistors wherein one or more transistors having a gate region with a uniform gate length and a body contact region abutted to a conduction channel under the gate region to improve mitigation of the kink effect, including, but not limited to, the FETs in FIGS. 2A-2C, 3A-3C, 4A-4B, and 5A-5B, and fabricated according to the exemplary fabrication processes in FIGS. 7 and 8A-8C; and

FIG. 11 is a block diagram of an exemplary processor-based system that can include components comprising transistors wherein one or more transistors having a gate region with a uniform gate length and a body contact region abutted to a conduction channel under the gate region to improve mitigation of the kink effect, including, but not limited to, the FETs in FIGS. 2A-2C, 3A-3C, 4A-4B, and 5A-5B, and fabricated according to the exemplary fabrication processes in FIGS. 7 and 8A-8C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise. The term “directly adjacent” as used herein means adjoining something as shown in the Figures.

Aspects disclosed herein include a transistor having a gate region with a uniform gate length and a body contact region abutted to a conduction channel under the gate region to improve mitigation of the kink effect, and related methods. The transistor is provided that includes the conduction channel formed from a semiconductor layer (i.e., silicon). The transistor may be a silicon-on-insulator (SOI) transistor as an example. A source region and a drain region of the transistor are formed on opposite sides of the conduction channel in the semiconductor layer by implanting or diffusing doping material of a first polarity in the semiconductor layer. A gate region is formed on an insulating layer that is adjacent to the conduction channel to generate an electric field in the conduction channel and control the flow of current in the conduction channel. The gate region has a gate length and a gate width. The transistor has a body contact region having a second polarity and directly adjacent to the second side of the conduction channel creating a body interface between the body contact region and the conduction channel. The gate length is uniform throughout the entire gate width including where the body contact region is directly adjacent to the conduction channel.

In this regard, when bias between the gate and source regions (Vgs) is applied and increased, an electric field under the gate region is formed that repels holes (the majority carriers in a p-well (a.k.a. p-type doped substrate for an n-type transistor)) away from the region directly under the gate forming a depletion region. The body contact region pulls holes formed in the depletion region through the body interface with the conduction channel. Since the gate length is uniform throughout the gate width, the holes are pulled without negatively impacting the performance of the transistor. In short, having a uniform gate length can reduce threshold voltage variations, inconsistent channel lengths, timing issues, enhanced short-channel effects, and increased variability, all of which can degrade the overall performance and reliability of the CMOS transistor. Additionally, by abutting the body contact region to the conduction channel while maintaining the gate length, more body interfaces may be added to design transistors to pull more holes created at higher Vgs voltages and flatten out the kink effect at those higher Vgs voltages.

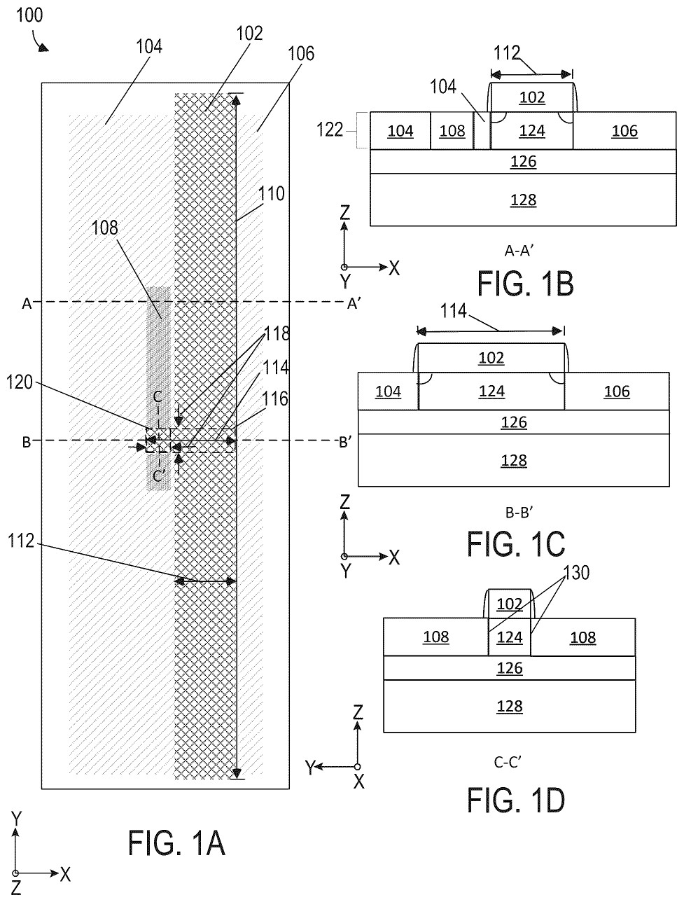

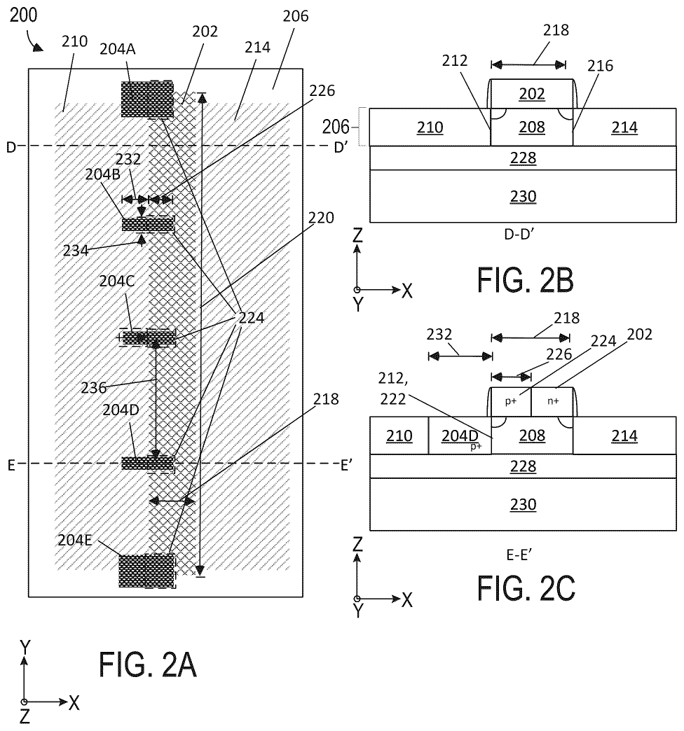

Before discussing exemplary aspects starting with FIG. 2A, a conventional transistor having a body terminal and a gate region with a non-uniform gate length is discussed. In this regard, FIG. 1A is a top view of a body butted to source (BBS) n-type FET 100 having a gate region 102 with a non-uniform gate length. The FET 100 includes a source region 104 which extends in a first horizontal direction (X-axis direction) and a second horizontal direction (Y-axis direction) and is doped with an n+ polarity, and a drain region 106 which extends in the first horizontal direction (X-axis direction) and the second horizontal direction (Y-axis direction) and is doped with an n+ polarity. The FET 100 also includes a body contact region 108 which extends in the first horizontal direction (X-axis direction) and the second horizontal direction (Y-axis direction) and is doped with a p+ polarity. The gate region 102 extends in the first horizontal direction (X-axis direction) and the second horizontal direction (Y-axis direction) and is formed of polycrystalline silicon (a.k.a. poly). The gate region 102 has a gate width 110. The FET 100 includes two gate lengths—gate length 112 and gate length 114. A portion 116 of the gate region 102 has the gate length 114 and a gate width 118. The gate region 102 shadows a conduction channel 124 in a third direction (the Z-direction) which is shown in FIG. 1D. In other words, wherever there is a gate region 102, a conduction channel is below the gate region 102.

A portion 120 of the gate region 102 has a length equal to the width 118, and the width 118. A body interface between the body contact region and the conduction channel is under the portion 120 and will be illustrated in FIG. 1D. In operation, when a voltage (Vgs) is applied to the gate region 102, holes that form in the depletion region in the conduction channel are removed through the body interface into the body contact region 108. However, the non-uniform gate lengths (i.e., gate length 112 and gate length 114) can lead to threshold voltage variations, inconsistent channel lengths, timing issues, enhanced short-channel effects, and increased variability, all of which can degrade the overall performance and reliability of the FET 100. As the voltage (Vgs) increases, the holes begin to accumulate in the p-well creating internal resistance in the transistor. To address this, a designer may need to modify the FET 100 to include more body interfaces to alleviate the accumulation of holes and reduce the distance the holes travel to a body interface by adding more portions of the gate region 102 to intersect with the body contact region 108, like the portions 116 to form more body interfaces. For each additional portion, the previous negative effects resulting from non-uniform gate lengths will be amplified. A measure of proximal effectiveness for removing holes from the FET 100 is the ratio of area of the portion 120 relative to the area of the entire gate region 102. The higher the ratio, the more effective the transistor pulls holes through the body contact region 108. That ratio for the FET 100 is very small (˜0.15%); consequently, long channel analog has a more significant impact since longer channel lengths have large FET area without a corresponding scaling in the body area

FIG. 1B is a side view of the FET at cut line A-A′ in FIG. 1A. The FET 100 includes a semiconductor layer 122. The semiconductor layer 122 includes the source region 104, the drain region 106, the body contact region 108, and a conduction channel 124 (i.e., a p-well in an n-type transistor). The FET 100 is adjacent to an insulation layer 126 in the third direction (Z-axis direction). The insulation layer 126 extends in the first horizontal direction (X-axis direction) and the second horizontal direction (Y-axis direction) and may include various oxides including silicon oxide (SiO). The insulation layer 126 is adjacent to a substrate layer 128 in the third direction (Z-axis direction). The substrate layer 128 extends in the first horizontal direction (X-axis direction) and the second horizontal direction (Y-axis direction) and may be made of silicon (Si). At cut-line A-A′, the gate region 102 has the gate length 112. Additionally, the body contact region 108 is between portions of the source region 104 in the first direction (X-axis direction).

FIG. 1C is a side view of the FET at cut line B-B′ in FIG. 1A illustrating the difference in gate length between cut line B-B′ and cut line A-A′. At cut line B-B′, the gate region 102 has the gate length 114 which is longer than the gate length 112 at cut line A-A′.

FIG. 1D is a side view of the FET at cut line C-C′ in FIG. 1A illustrating body interfaces 130 between the conduction channel 124 (p-well) and the body contact region 108. The body interfaces 130 are shown between the conduction channel 124 and the body contact region 108 through which holes travel from the conduction channel 124 to the body contact region 108.

Turning to exemplary aspects, FIGS. 2A-2C will be discussed together and are directed to an exemplary embodiment of an n-type FET (NFET) 200 having a gate region 202 with a uniform gate length and a body contact region 204A-204E abutted to a conduction channel 208 under the gate region 202 to improve mitigation of the kink effect. FIG. 2A is a top view of the NFET 200. The NFET 200 has a semiconductor layer 206. The semiconductor layer 206 includes the conduction channel 208 (see FIGS. 2B-2C) and a source region 210 of a first polarity (i.e., n+) adjacent to a first side 212 of the conduction channel 208 (see FIG. 2B). The semiconductor layer 206 also includes a drain region 214 of the first polarity (i.e., n+) adjacent to a second side 216 of the conduction channel 208 opposite the first side 212 in the first direction (X-direction) (see FIG. 2B). The semiconductor layer 206 also includes the gate region 202 extending in the first direction (X-axis direction) and the second direction (Y-axis direction). The gate region 202 is adjacent to the conduction channel 208 in the third direction (Z-axis direction) (FIGS. 2B-2C). The gate region 202 has a gate length 218 extending in the first direction (X-axis direction) and a gate width 220 extending in the second direction (Y-axis direction), wherein the gate length 218 is uniform throughout the entire gate width 220. The semiconductor layer 206 also includes the body contact region 204A-204E having the second polarity (i.e., p+) and directly adjacent, in the first direction (X-axis direction), to the first side 212 of the conduction channel 208 (see FIG. 2C) and forming a body interface 222. The body contact region 204A-204E includes sub-body region 204A, sub-body region 204B, sub-body region 204C, sub-body region 204D, and sub-body region 204E. During fabrication of the body contact region 204A-204E, the doping for the body contact region 204A-204E deposits into a sub-area portion 224 of the gate region 202 and is illustrated in FIG. 2C with “p+”. The sub-area portion 224 of the gate region 202 has a length 226 (see FIG. 2C). During fabrication of the drain region 214, the doping for the drain region 214 deposits into the gate region 202 and is illustrated in FIG. 2C with “n+”. The body contact region 204A-204E is electrically coupled to the source region 210.

As illustrated in FIGS. 2B and 2C, the NFET 200 is adjacent to an insulation layer 228 in the third direction (Z-axis direction). The insulation layer 228 extends in the first horizontal direction (X-axis direction) and the second horizontal direction (Y-axis direction) and may include various oxides including silicon oxide (SiO). The insulation layer 228 is adjacent to a substrate layer 230 in the third direction (Z-axis direction). The substrate layer 230 extends in the first horizontal direction (X-axis direction) and the second horizontal direction (Y-axis direction) and may be made of silicon (Si).

The sub-body regions 204A, 204B, 204C, 204D, 204E each have a body length 232, a body width 234, and have a body interface, such as the body interface 222, to pull holes when a bias (Vgs) is applied to the gate region 202 while maintaining a uniform gate width 220. Although not shown, only one sub-body region may be needed to pull holes when a bias (Vgs) is applied depending on the level of the bias. The sub-body regions 204A-204E are distributed across the gate width 220. For a gate width 220 of 12 micrometers (μm), a distance 236 between sub-body regions 204C and 204D measured from the centers of the sub-body regions 204C and 204D may be between 2-3μm. Moreover, the distance between any two adjacent sub-body regions, 204D-204E for example, may be equal. In other words, the sub-body regions 204A-204E are distributed equally across the width of the gate region 202. By deploying multiple sub-body regions 204A-204E, larger biases (Vgs) may be deployed without a kink effect because the corresponding body interfaces 222 of the sub-body regions 204A-204E may pull holes when bias is applied and reduce resistance in the conduction channel 208 from hole accumulation in the conduction channel 208. Additionally, the distribution of the sub-body regions 204A-204E provides holes to travel short distances between any point in the conduction channel 208 and any body interface 222 corresponding to the sub-body regions 204A-204E. A measure of proximal effectiveness for removing holes from the NFET 200 is the ratio of sub-area portions 224 to the area of the entire gate region 202 which is the gate length 218 times the gate width 220. The higher the ratio, the more effectively the transistor pulls holes through the body contact region 204. The ratio for the exemplary NFET 200 is 3.6%. The measure of proximal effectiveness for FETs, similar to NFET 200, which achieves mitigation of the Kink effect may be between 2% and 5%.

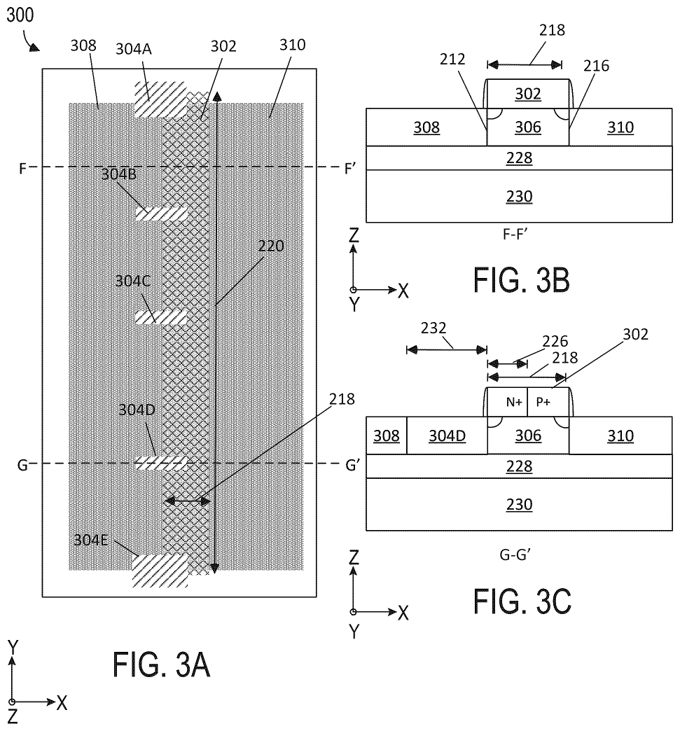

FIGS. 3A-3C are directed to an exemplary embodiment of a p-type FET (PFET) 300 having a gate region 302 with a uniform gate length 218 and a body contact region 304A-304E abutted to a conduction channel 306 (i.e., n-well) under the gate region 302 to improve mitigation of the kink effect and will be discussed together. FIG. 3A is a top view of the PFET 300. FIG. 3B is a side view of the PFET 300 at cut line F-F′ in FIG. 3A. FIG. 3C is a side view of the PFET 300 at cut line G-G′ in FIG. 3A. Common elements between the NFET 200 in FIG. 2A-2C and the PFET 300 in FIG. 3A-3C are shown with common element numbers. The main difference between the PFET 300 and the NFET 200 of FIGS. 2A-2C are the polarities of the gate region 302, body contact region 304A-304E, source region 308, drain region 310, and the conduction channel 306.

The body contact region 304A-304E has the n+ polarity. The PFET 300 includes a source region 308 having the p+ polarity and a drain region 310 having the p+ polarity.

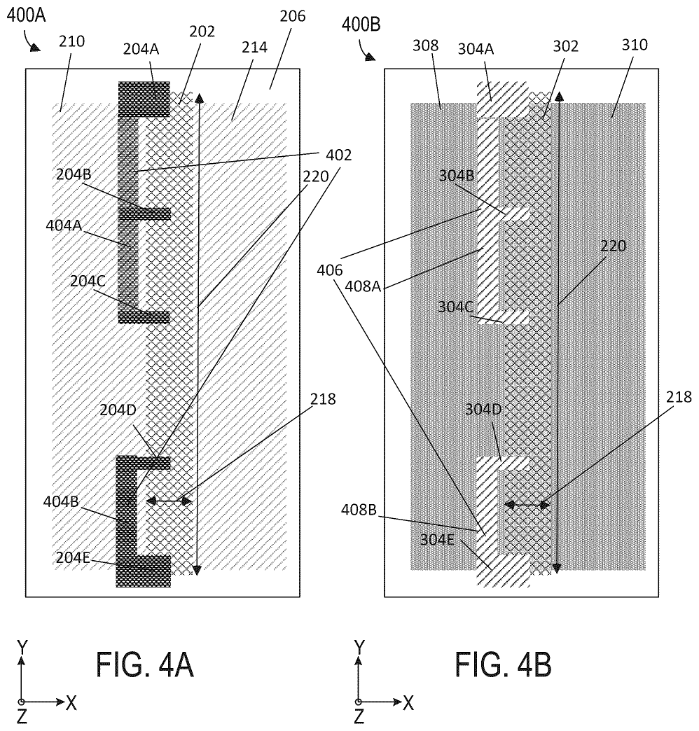

FIGS. 4A-4B are directed to transistors of another exemplary embodiment of transistors having a gate region with a uniform gate length and a body contact region abutted to a conduction channel under the gate region to improve mitigation of the kink effect wherein the transistors of FIG. 4A-4B have sub-body regions that do not by themselves meet a foundry's area requirement in the first and second directions (X-, Y-axis directions). FIG. 4A is a top view of an n-type transistor 400A which has the sub-body regions 204A-204E that do not by themselves meet a foundry's area requirement in the first and second directions (X-, Y-axis directions). Common elements between the NFET 200 in FIGS. 2A-2C and the NFET 400A in FIG. 4A are shown with common element numbers. As a result, body contact region 402 has two base portions, 404A and 404B, extending in the first direction (X-axis direction) and the second direction (Y-axis direction). Base portion 404A is orthogonal and couples to the sub-body regions 204A-204C. Base portion 404B is orthogonal and couples to the sub-body regions 204D, 204E.

FIG. 4B is a top view of another exemplary embodiment of a p-type transistor 400B which has the sub-body regions 304A-304E that do not by themselves meet a foundry's area requirement in the first and second directions (X-, Y-axis directions). Common elements between the NFET 200 and PFET 300 in FIG. 2A-2C and 3A-3C and the PFET 400B in FIG. 4B are shown with common element numbers. As a result, body contact region 406 has two base portions, 408A and 408B, extending in the first direction (X-axis direction) and the second direction (Y-axis direction). Base portion 408A is orthogonal and couples to the sub-body regions 304A-304C. Base portion 408B is orthogonal and couples to the sub-body regions 304D, 304E.

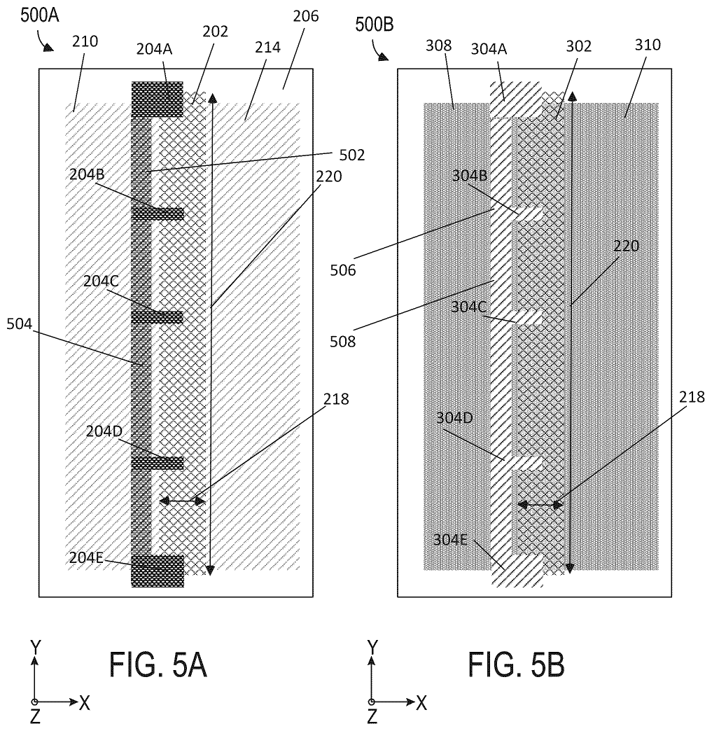

FIGS. 5A-5B are directed to transistors of another exemplary embodiment of transistors having a gate region with a uniform gate length and a body contact region abutted to a conduction channel under the gate region to improve mitigation of the kink effect wherein the transistors of FIG. 5A-5B have sub-body regions that do not by themselves meet a foundry's area requirement in the first and second directions (X-, Y-axis directions). FIG. 5A is a top view of an NFET 500A which has the sub-body regions 204A-204E that do not by themselves meet a foundry's area requirement in the first and second directions (X-, Y-axis directions). Common elements between the NFET 200 in FIG. 2A-2C and the NFET 500A in FIG. 5A are shown with common element numbers. As a result, body contact region 502 includes a base portion 504 which extends in the first direction (X-axis direction) and the second direction (Y-axis direction). The base portion 504 is orthogonal and couples to the sub-body regions 204A-204E.

FIG. 5B is a top view of another exemplary embodiment of a p-type transistor 500B which has the sub-body regions 304A-304E that do not by themselves meet a foundry's area requirement in the first and second directions (X-, Y-axis directions). Common elements between the NFET 200 in FIGS. 2A-2C, the PFET 300 in FIGS. 3A-3C and the PFET 500B in FIG. 5B are shown with common element numbers. As a result, body contact region 506 includes a base portion 508, extending in the first direction (X-axis direction) and the second direction (Y-axis direction). The base portion 508 is orthogonal and couples to the sub-body regions 304A-304E.

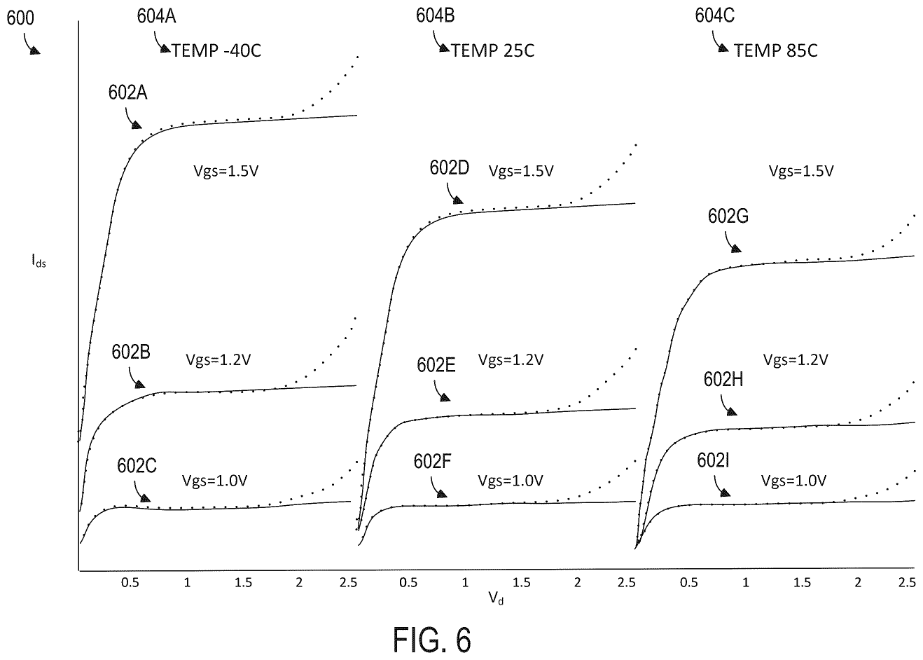

FIG. 6 is a graph 600 which illustrates a series of simulated current/voltage characteristic curves 602A-602I comparing the NFET 100 of FIGS. 1A-1C (i.e., dotted curves) and the NFET 500A of FIG. 5A (i.e., solid curves) having a gate region with a uniform gate length and a body contact region abutted to a conduction channel under the gate region to improve mitigation of the kink effect over various operating temperatures 604A-604C and various gate voltages (Vgs). As illustrated in the graphs, at all simulated temperatures and gate voltages, the NFET 500A of FIG. 5A has a much flatter drain source current (Ids) than the NFET 100 of FIGS. 1A-1C. In other words, the kink effect experienced by the NFET 100 of FIGS. 1A-1C which is illustrated by the rapidly increasing drain source current (Ids) is mitigated by the NFET 500A of FIG. 5A illustrated by the flattened drain source current (Ids) at the same higher gate voltages.

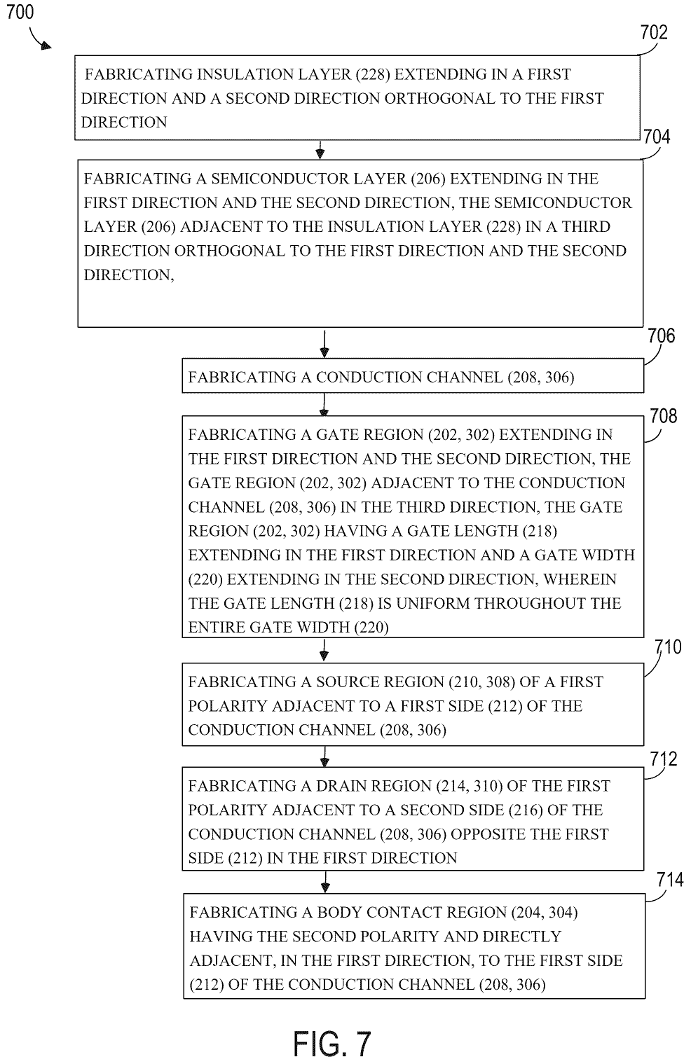

FIG. 7 is a flowchart illustrating an exemplary fabrication process 700 for fabricating an FET having a gate region with a uniform gate length and a body contact region abutted to a conduction channel under the gate region to improve mitigation of the kink effect including, but not limited to, the NFETs 200, 400A, 500A in FIGS. 2A-2C, 4A, and 5A and the PFETs 300, 400B, 500B in FIGS. 3, 4B, and 5B. In this regard, a first exemplary step for fabricating an FET having a gate region with a uniform gate length and a body contact region abutted to a conduction channel under the gate region to improve mitigation of the kink effect can include fabricating an insulation layer 228 extending in a first direction and a second direction orthogonal to the first direction (block 702 in FIG. 7). The next step in the fabrication process 700 can include fabricating a semiconductor layer 206 extending in the first direction and the second direction, the semiconductor layer 206 adjacent to the insulation layer 228 in a third direction orthogonal to the first direction and the second direction (block 704 in FIG. 7).

The next steps in the fabrication process 700 include the following sub-steps to fabricate the semiconductor layer 206. The next step in the fabrication process 700 can include fabricating a conduction channel 208, 306 (block 706 in FIG. 7). The next step in the fabrication process 700 can include fabricating a gate region 202, 302 extending in the first direction and the second direction, the gate region 202, 302 adjacent to the conduction channel 208, 306 in the third direction, the gate region 202, 302 having a gate length 218 extending in the first direction and a gate width 220 extending in the second direction, wherein the gate length 218 is uniform throughout the entire gate width 220 (block 708 in FIG. 7). The next step in the fabrication process 700 can include fabricating a source region 210, 308 of a first polarity adjacent to a first side 212 of the conduction channel 208, 306 (block 710 in FIG. 7). The next step in the fabrication process 700 can include fabricating a drain region 214, 310 of the first polarity adjacent to a second side 216 of the conduction channel 208, 306 opposite the first side 212 in the first direction (block 712 in FIG. 7). The next step in the fabrication process 700 can include fabricating a body contact region 204, 304 having a second polarity and directly adjacent, in the first direction, to the first side 212 of the conduction channel 208, 306 (block 714 in FIG. 7).

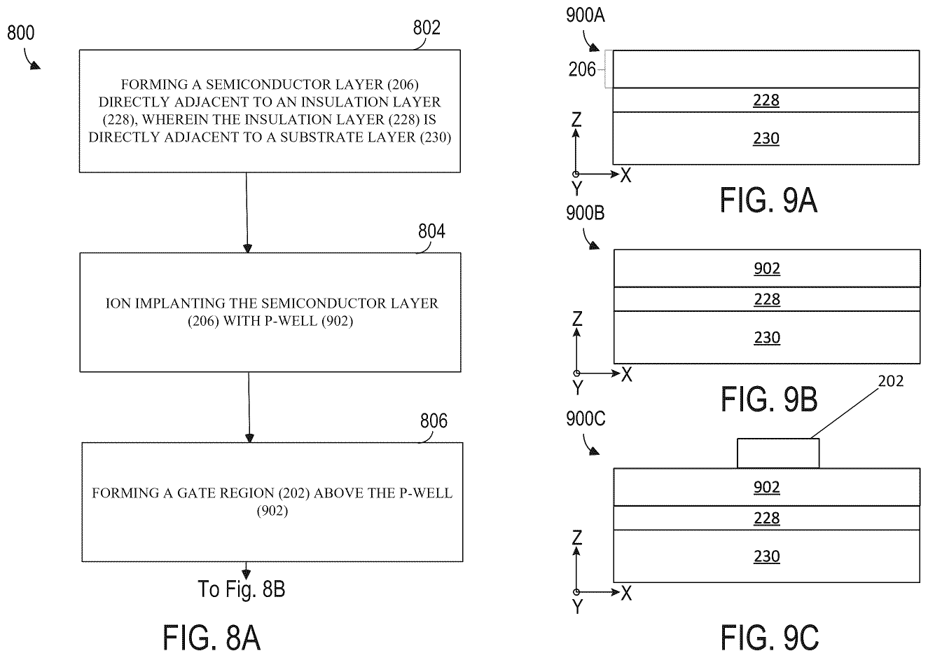

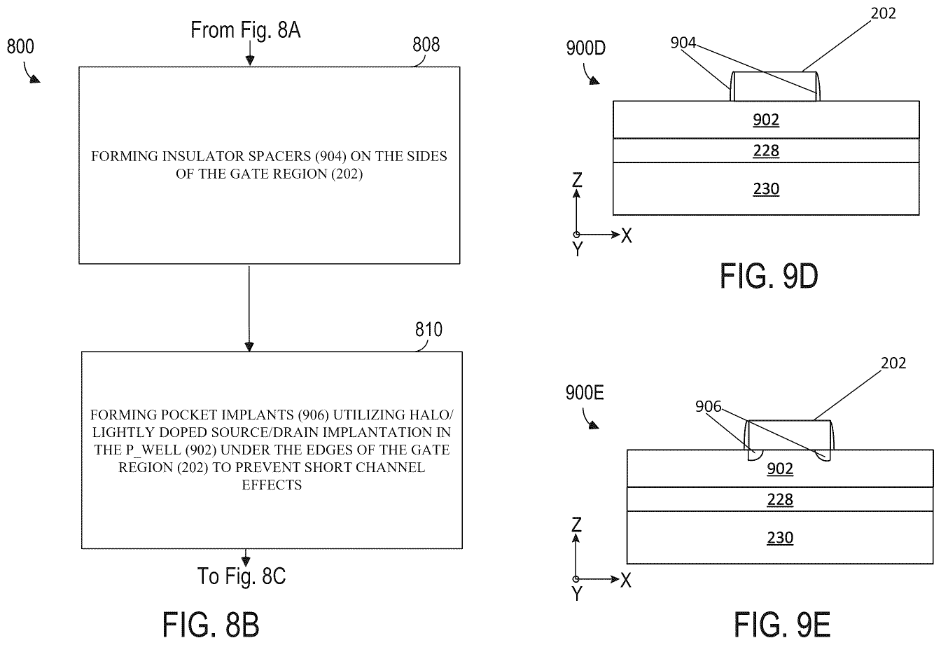

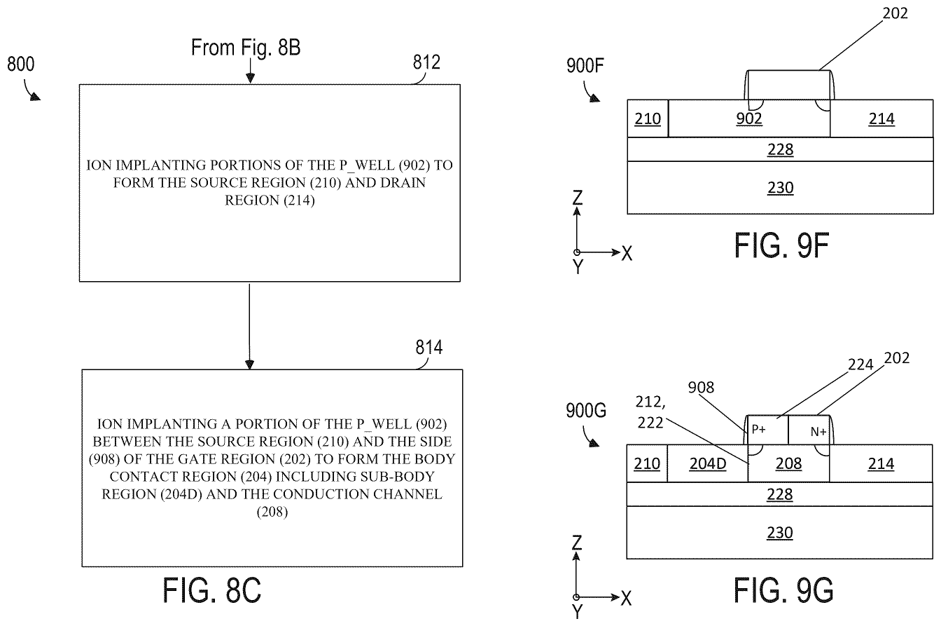

FIGS. 8A-8C are a flowchart illustrating another exemplary fabrication process 800 for fabricating an n-type transistor having a gate region with a uniform gate length and a body contact region abutted to a conduction channel under the gate region to improve mitigation of the kink effect, including, but not limited to, the n-type transistors in FIGS. 2A-2C, 4A, and 5A, and is applicable to the p-type transistors of FIGS. 3A-3C, 4B, and 5B. The fabrication process 800 will be discussed in conjunction with the NFET 200 in FIGS. 2A-2C. FIGS. 9A-9H are exemplary fabrication stages during fabrication of the n-type transistor according to the fabrication process in FIGS. 8A-8C.

In this regard, as shown in fabrication stage 900A in FIG. 9A, an exemplary step in the fabrication process 800 includes forming a semiconductor layer 206 directly adjacent to an insulation layer 228, wherein the insulation layer 228 is directly adjacent to a substrate layer 230 (block 802 in FIG. 8A). As shown in fabrication stage 900B in FIG. 9B, a next step in the process 800 can include ion implanting the semiconductor layer 206 with a p-well 902 (block 804, FIG. 8A). As shown in fabrication stage 900C in FIG. 9C, a next step in the process 800 can include forming a gate region 202 above the p-well 902. The gate region 202 has a gate length extending in the first direction (X-axis direction) and a gate width extending in the second direction (Y-axis direction), wherein the gate length is uniform throughout the entire gate width (block 806, FIG. 8A).

As shown in fabrication stage 900E in FIG. 9E, a next step in the process 800 can include forming insulator spacers 904 on the sides of the gate region 202 (block 808 in FIG. 8B). As shown in fabrication stage 900F in FIG. 9F, a next step in the process 800 can include forming pocket implants 906 utilizing halo/lightly-doped source/drain implantation in the p-well 902 under the edges of the gate region 202 to prevent short channel effects (block 810, FIG. 8B).

As shown in fabrication stage 900G in FIG. 9G, a next step in the process 800 can include ion implanting portions of the p-well 902 with N+ source/drain implant to form the source region 210 and drain region 214 (block 812 in FIG. 8C). As shown in fabrication stage 900H in FIG. 9H, a next step in the process 800 can include ion implanting with a P+ implant a portion of the p-well 902 between the source region 210 and a side 908 of the gate region 202 to form the body contact region 204 including the sub-body region 204D and the conduction channel 208 (a.k.a the p-well 902 remaining under the gate region 202) (block 814, FIG. 8C). In so doing, a sub-area portion 224 of the gate region 202 will be lightly doped with the same polarity at the body contact region 204. Silicide will be implanted in the gate region 202 and in the source region 210 and the body contact region 204 to reduce the source/drain/gate access resistance and prevent inherent diodes caused by the previous implanting steps.

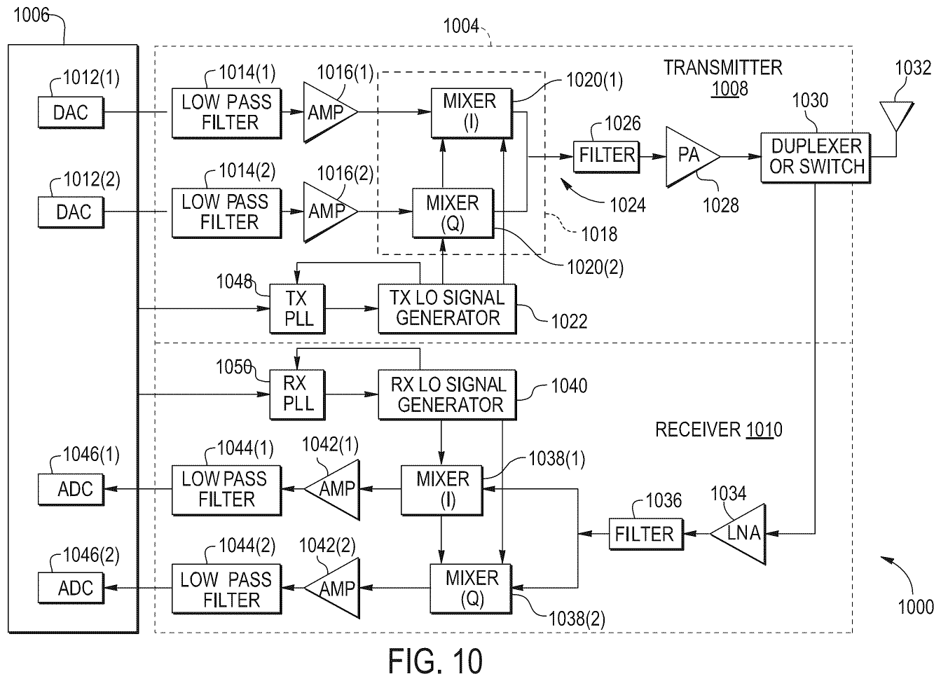

FIG. 10 is a block diagram of an exemplary wireless communications device that includes radio-frequency (RF) components comprising transistors wherein one or more transistors have a gate region with a uniform gate length and a body contact region abutted to a conduction channel under the gate region to improve mitigation of the kink effect, including, but not limited to, the FETs in FIGS. 2A-2C, 3A-3C, 4A-4B, and 5A-5B, and fabricated according to the exemplary fabrication processes in FIGS. 7 and 8A-8C.

As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals (e.g., I and Q output currents) for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

A semiconductor die including transistors wherein one or more transistors have a gate region with a uniform gate length and a body contact region abutted to a conduction channel under the gate region to improve mitigation of the kink effect as disclosed in aspects described herein may be provided in or integrated into an IC and deployed in any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

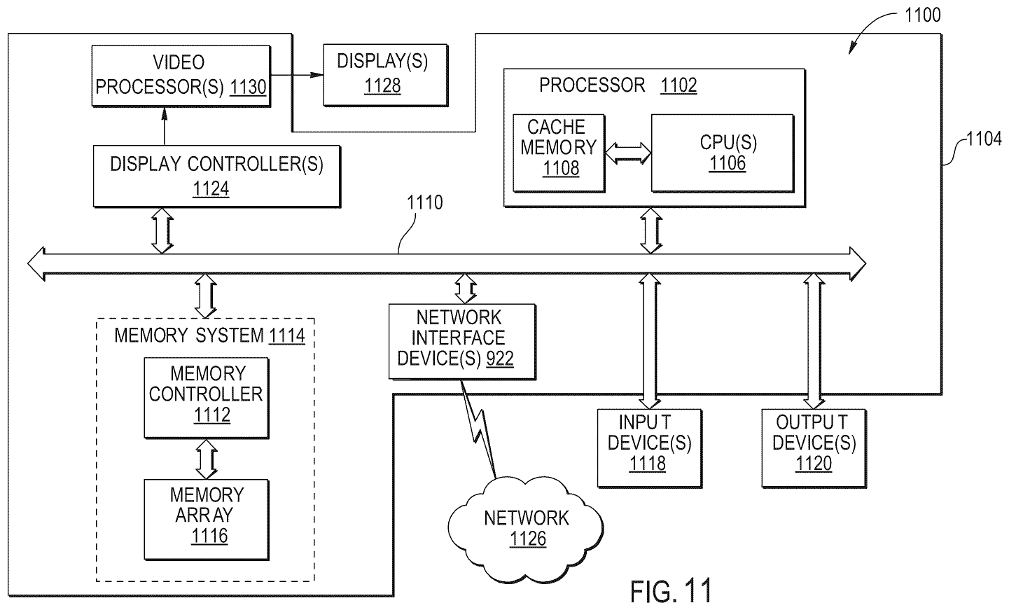

In this regard, FIG. 11 is a block diagram of an exemplary processor-based system that can include components comprising transistors wherein one or more transistors have a gate region with a uniform gate length and a body contact region abutted to a conduction channel under the gate region to improve mitigation of the kink effect, including, but not limited to, the transistors in FIGS. 2A-2C, 3A-3C, 4A-4B, and 5A-5B, and fabricated according to the exemplary fabrication processes in FIGS. 7 and 8A-8C.

In this example, the processor-based system 1100 includes a processor 1102 deployed on a semiconductor die 1104 including transistors wherein one or more transistors have a gate region with a uniform gate length and a body contact region abutted to a conduction channel under the gate region to improve mitigation of the kink effect as disclosed herein and includes one or more central processing units (captioned as “CPUs” in FIG. 11) 1106, which may also be referred to as CPU cores or processor cores. The processor 1102 may have cache memory 1108 coupled to the processor 1102 for rapid access to temporarily stored data. The processor 1102 is coupled to a system bus 1110 and can intercouple server and client devices included in the processor-based system 1100. As is well known, the processor 1102 communicates with these other devices by exchanging address, control, and data information over the system bus 1110. For example, the processor 1102 can communicate bus transaction requests to a memory controller 1112, as an example of a client device. Although not illustrated in FIG. 11, multiple system buses 1110 could be provided, wherein each system bus 1110 constitutes a different fabric.

Other server and client devices can be connected to the system bus 1110 and deployed in a die including transistors wherein one or more transistors have a gate region with a uniform gate length and a body contact region abutted to a conduction channel under the gate region to improve mitigation of the kink effect. As illustrated in FIG. 11, these devices can include a memory system 1114 that includes the memory controller 1112 and a memory array(s) 1116, one or more input devices 1118, one or more output devices 1120, one or more network interface devices 1122, and one or more display controllers 1124, as examples. The input device(s) 1118 can include any type of input device, including but not limited to input keys, switches, voice processors, etc. The output device(s) 1120 can include any type of output device, including, but not limited to, audio, video, other visual indicators, etc. The network interface device(s) 1122 can be any device configured to allow exchange of data to and from a network 1126. The network 1126 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1122 can be configured to support any type of communications protocol desired.

The processor 1102 may also be configured to access the display controller(s) 1124 over the system bus 1110 to control information sent to one or more displays 1128. The display controller(s) 1126 sends information to the display(s) 1126 to be displayed via one or more video processors 1130, which process the information to be displayed into a format suitable for the display(s) 1128. The display controller(s) 1124 and/or the video processors 1130 may comprise or be integrated into a GPU. The display(s) 1128 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A transistor, comprising:
   an insulation layer extending in a first direction and a second direction orthogonal to the first direction; and
   a semiconductor layer extending in the first direction and the second direction, the semiconductor layer adjacent to the insulation layer in a third direction orthogonal to the first direction and the second direction, the semiconductor layer comprising:
      a conduction channel;
      a source region of a first polarity and adjacent to a first side of the conduction channel;
      a drain region of the first polarity and adjacent to a second side of the conduction channel opposite the first side in the first direction;
      a gate region extending in the first direction and the second direction, the gate region adjacent to the conduction channel in the third direction, the gate region having a gate length extending in the first direction and a gate width extending in the second direction, wherein the gate length is uniform throughout the gate width; and
      a body contact region having a second polarity and directly adjacent, in the first direction, to the first side of the conduction channel.
2. The transistor of clause 1, wherein:
   the gate region has a sub-area extending in the first direction and the second direction, the sub-area having the second polarity;
   the gate region has a gate area extending in the first direction and the second direction and defined by the gate width and the gate length; and
   a ratio of the sub-area to the gate area is greater than or equal to 2%.
3. The transistor of clause 1 or 2, wherein:
   the body contact region comprises:
      a plurality of sub-body regions, the plurality of sub-body regions distributed across the gate width.
4. The transistor of clause 3, wherein a distance between any two adjacent sub-body regions of the plurality of sub-body regions is between 2 and 3 micrometers (μm).
5. The transistor of clause 3, wherein each of the plurality of sub-body regions has a center, wherein distances in the second direction between the center of any two of the plurality of sub-body regions are equal.
6. The transistor of clause 3, wherein the body contact region further comprises:
   a base portion extending in the second direction and adjacent to the source region in the first direction, the base portion directly adjacent to the plurality of sub-body regions in the first direction.
7. The transistor of clause 6, wherein the base portion comprises:
   a first base portion coupled to a first set of the plurality of sub-body regions; and
   a second base portion coupled to a second set of the plurality of sub-body regions.
8. The transistor of any of clauses 1-7, wherein:
   the first polarity is n+ and the second polarity is p+.
9. The transistor of any of clauses 1-7, wherein:
   the first polarity is p+ and the second polarity is n+.
10. The transistor of any of clauses 1-7, wherein the body contact region is electrically coupled to the source region.
11. A method for fabricating a transistor to improve mitigation of a kink effect, comprising:
   fabricating an insulation layer extending in a first direction and a second direction orthogonal to the first direction; and
   fabricating a semiconductor layer extending in the first direction and the second direction, the semiconductor layer adjacent to the insulation layer in a third direction orthogonal to the first direction and the second direction, wherein fabricating the semiconductor layer comprises:
      fabricating a conduction channel;
      fabricating a gate region extending in the first direction and the second direction, the gate region adjacent to the conduction channel in the third direction, the gate region having a gate length extending in the first direction and a gate width extending in the second direction, wherein the gate length is uniform throughout the gate width;
      fabricating a source region of a first polarity and adjacent to a first side of the conduction channel;
      fabricating a drain region of the first polarity and adjacent to a second side of the conduction channel opposite the first side in the first direction; and
      fabricating a body contact region having a second polarity and directly adjacent, in the first direction, to the first side of the conduction channel.
12. The method of clause 11, wherein:
   the gate region has a sub-area extending in the first direction and the second direction, the sub-area having the second polarity;
   the gate region has a gate area extending in the first direction and the second direction and defined by the gate width and the gate length; and
   a ratio of the sub-area to the gate area is greater than or equal to 2%.
13. The method of clause 11 or 12, wherein:
   the body contact region comprises:
      a plurality of sub-body regions, the plurality of sub-body regions distributed equally across the gate width.
14. The method of clause 13, wherein a distance between any two adjacent sub-body regions of the plurality of sub-body regions is between 2 and 3 micrometers (μm).
15. The method of clause 13, wherein each of the plurality of sub-body regions has a center, wherein distances in the second direction between the center of any two of the plurality of sub-body regions are equal.
16. The method of clause 13, wherein the body contact region further comprises:
   a base portion extending in the second direction and adjacent to the source region in the first direction, the base portion directly adjacent to the plurality of sub-body regions in the first direction.
17. The method of clause 16, wherein the base portion comprises:
   a first base portion coupled to a first set of the plurality of sub-body regions; and
   a second base portion coupled to a second set of the plurality of sub-body regions.
18. An n-type field-effect transistor (FET) (NFET), comprising:
   an insulation layer extending in a first direction and a second direction orthogonal to the first direction; and
   a semiconductor layer extending in the first direction and the second direction, the semiconductor layer adjacent to the insulation layer in a third direction orthogonal to the first direction and the second direction, the semiconductor layer comprising:
      a conduction channel;
      a n-type source region adjacent to a first side of the conduction channel;
      a n-type drain region adjacent to a second side of the conduction channel opposite the first side in the first direction;
      a gate region extending in the first direction and the second direction, the gate region adjacent to the conduction channel in the third direction, the gate region having a gate length extending in the first direction and a gate width extending in the second direction, wherein the gate length is uniform throughout the gate width; and
      a p-type body contact region directly adjacent, in the first direction, to the first side of the conduction channel and the n-type source region.
19. The NFET of clause 18, wherein:
   the gate region has a sub-area extending in the first direction and the second direction, the sub-area having a p-type polarity;
   the gate region has a gate area extending in the first direction and the second direction and defined by the gate width and the gate length; and
   a ratio of the sub-area to the gate area is greater than or equal to 2%.
20. The NFET of clause 18 or 19, wherein:
   the p-type body contact region comprises:
      a plurality of sub-body regions, the plurality of sub-body regions distributed equally across the gate width.

What is claimed is:

1. A transistor, comprising:
an insulation layer extending in a first direction and a second direction orthogonal to the first direction; and
a semiconductor layer extending in the first direction and the second direction, the semiconductor layer adjacent to the insulation layer in a third direction orthogonal to the first direction and the second direction, the semiconductor layer comprising:
a conduction channel;
a source region of a first polarity and adjacent to a first side of the conduction channel;
a drain region of the first polarity and adjacent to a second side of the conduction channel opposite the first side in the first direction;
a gate region extending in the first direction and the second direction, the gate region adjacent to the conduction channel in the third direction, the gate region having a gate length extending in the first direction and a gate width extending in the second direction, wherein the gate length is uniform throughout the gate width; and
a body contact region having a second polarity and directly adjacent, in the first direction, to the first side of the conduction channel.

2. The transistor of claim 1, wherein:
the gate region has a sub-area extending in the first direction and the second direction, the sub-area having the second polarity;
the gate region has a gate area extending in the first direction and the second direction and defined by the gate width and the gate length; and
a ratio of the sub-area to the gate area is greater than or equal to 2%.

3. The transistor of claim 1, wherein:
the body contact region comprises:
a plurality of sub-body regions, the plurality of sub-body regions distributed across the gate width.

4. The transistor of claim 3, wherein a distance between any two adjacent sub-body regions of the plurality of sub-body regions is between 2 and 3 micrometers (μm).

5. The transistor of claim 3, wherein each of the plurality of sub-body regions has a center, wherein distances in the second direction between the center of any two of the plurality of sub-body regions are equal.

6. The transistor of claim 3, wherein the body contact region further comprises:
a base portion extending in the second direction and adjacent to the source region in the first direction, the base portion directly adjacent to the plurality of sub-body regions in the first direction.

7. The transistor of claim 6, wherein the base portion comprises:
a first base portion coupled to a first set of the plurality of sub-body regions; and
a second base portion coupled to a second set of the plurality of sub-body regions.

8. The transistor of claim 1, wherein:
the first polarity is n+and the second polarity is p+.

9. The transistor of claim 1, wherein:
the first polarity is p+and the second polarity is n+.

10. The transistor of claim 1, wherein the body contact region is electrically coupled to the source region.

11. A method for fabricating a transistor to improve mitigation of a kink effect, comprising:
fabricating an insulation layer extending in a first direction and a second direction orthogonal to the first direction; and
fabricating a semiconductor layer extending in the first direction and the second direction, the semiconductor layer adjacent to the insulation layer in a third direction orthogonal to the first direction and the second direction, wherein fabricating the semiconductor layer comprises:
fabricating a conduction channel;
fabricating a gate region extending in the first direction and the second direction, the gate region adjacent to the conduction channel in the third direction, the gate region having a gate length extending in the first direction and a gate width extending in the second direction, wherein the gate length is uniform throughout the gate width;
fabricating a source region of a first polarity and adjacent to a first side of the conduction channel;
fabricating a drain region of the first polarity and adjacent to a second side of the conduction channel opposite the first side in the first direction; and
fabricating a body contact region having a second polarity and directly adjacent, in the first direction, to the first side of the conduction channel.

12. The method of claim 11, wherein:
the gate region has a sub-area extending in the first direction and the second direction, the sub-area having the second polarity;
the gate region has a gate area extending in the first direction and the second direction and defined by the gate width and the gate length; and
a ratio of the sub-area to the gate area is greater than or equal to 2%.

13. The method of claim 11, wherein:
the body contact region comprises:
a plurality of sub-body regions, the plurality of sub-body regions distributed equally across the gate width.

14. The method of claim 13, wherein a distance between any two adjacent sub-body regions of the plurality of sub-body regions is between 2 and 3 micrometers (μm).

15. The method of claim 13, wherein each of the plurality of sub-body regions has a center, wherein distances in the second direction between the center of any two of the plurality of sub-body regions are equal.

16. The method of claim 13, wherein the body contact region further comprises:
a base portion extending in the second direction and adjacent to the source region in the first direction, the base portion directly adjacent to the plurality of sub-body regions in the first direction.

17. The method of claim 16, wherein the base portion comprises:
a first base portion coupled to a first set of the plurality of sub-body regions; and
a second base portion coupled to a second set of the plurality of sub-body regions.

18. An n-type field-effect transistor (FET) (NFET), comprising:
an insulation layer extending in a first direction and a second direction orthogonal to the first direction; and
a semiconductor layer extending in the first direction and the second direction, the semiconductor layer adjacent to the insulation layer in a third direction orthogonal to the first direction and the second direction, the semiconductor layer comprising:
a conduction channel;
a n-type source region adjacent to a first side of the conduction channel;
a n-type drain region adjacent to a second side of the conduction channel opposite the first side in the first direction;
a gate region extending in the first direction and the second direction, the gate region adjacent to the conduction channel in the third direction, the gate region having a gate length extending in the first direction and a gate width extending in the second direction, wherein the gate length is uniform throughout the gate width; and
a p-type body contact region directly adjacent, in the first direction, to the first side of the conduction channel and the n-type source region.

19. The NFET of claim 18, wherein:
the gate region has a sub-area extending in the first direction and the second direction, the sub-area having a p-type polarity;
the gate region has a gate area extending in the first direction and the second direction and defined by the gate width and the gate length; and
a ratio of the sub-area to the gate area is greater than or equal to 2%.

20. The NFET of claim 18, wherein:
the p-type body contact region comprises:
a plurality of sub-body regions, the plurality of sub-body regions distributed equally across the gate width.
